(19) United States
(12) Patent Application Publication
(10) Pub. No.: US 2006/0163669 A1
(43) Pub. Date: Jul. 27, 2006

(54) Method of fabricating semiconductor device having silicide layer and semiconductor device fabricated thereby

(76) Inventors: Ki-seog Youn, Suwon-si (KR); Jong-hyon Ahn, Suwon-si (KR); Su-gon Bae, Suwon-si (KR)

Correspondence Address: LEE & MORSE, P.C., SUITE 2000, 1101 WILSON BOULEVARD, ARLINGTON, VA, 22209, US

(21) Appl. No.: 11/332,150

(22) Filed: Jan. 17, 2006

(30) Foreign Application Priority Data
Jan. 26, 2005 (KR) 10-2005-0007068

(51) Int. Cl. H01L 29/76

(52) U.S. Cl. 257/384

(57) ABSTRACT

A method of fabricating a semiconductor device having a silicide layer and a semiconductor device fabricated by the method are provided. The method may involve providing a semiconductor substrate having an active region and a field region, and forming a plurality of gate patterns on each of the active region and the field region. The plurality of gate patterns may each have a sidewall spacer. The plurality of gate patterns on the field region include at least two adjacent gate patterns. The method may involve forming a silicide blocking layer pattern that masks a portion of the field region that exists between each of the adjacent gate patterns on the field region. The method may also involve forming a silicide layer on the active region and any of the plurality of the gate patterns that are not masked by the silicide blocking layer pattern.

### BACKGROUND OF THE INVENTION

1. Field of the Invention

The invention relates to a method of fabricating a semiconductor device and a semiconductor device fabricated by the method. More particularly, the invention relates to a method of fabricating a semiconductor device having a silicide layer and a semiconductor device fabricated by the method.

2. Description of the Related Art

Semiconductor technology involves the formation of low resistance device forming regions. Silicide layers formed by making a silicon layer react with a metal material are widely used in the manufacture of low resistance device forming regions. Low resistance device forming regions including, for example, silicide layers help reduce response times of semiconductor devices.

Some semiconductor memories include a peripheral circuit region provided with various high resistance devices such as passive devices. A silicide blocking layer (SBL) may be deposited to prevent a silicide-layer from being formed on the peripheral circuit region that includes various high resistance devices.

FIGS. 1 through 5 illustrate cross-sectional views that sequentially illustrate various stages of a known method of fabricating a semiconductor device that includes a high resistance device forming region and a low resistance device forming region.

As shown in FIGS. 1 through 5, a high resistance device exists in region A and the semiconductor device having a silicide layer for embodying a low resistance device exists in region B.

As shown in FIG. 1, in the known method, a field isolation region is formed on a semiconductor substrate 10 by a shallow trench isolation (STI) method, thereby defining a field region 12 and an active region 11. Subsequently, a gate oxide layer 13, a gate pattern 14 and a sidewall spacer 16 are formed. The gate pattern 14 on the active region 11 is used as a gate electrode of a semiconductor device such as a memory device. The gate pattern 14 on the field region 12 is used to connect gate electrodes of each of cells formed on the active region 11.

As shown in FIG. 2, in the known method, a silicide blocking layer 20 is deposited on the entire surface of the semiconductor substrate 10. Subsequently, as shown in FIG. 3, the silicide blocking layer 20 formed on the low resistance device forming region B is removed. When the silicide blocking layer 20 is removed and a cleaning process is performed, recesses are created in the field region 12. The field region 12 includes an oxide layer. A relatively deep recess may be formed in a region between the adjacent gate patterns 14.

Next, as shown in FIGS. 4 and 5, in the known method, after a silicide layer 30 is formed in a self-aligned manner, a metal contact etch stop layer 40 and an interlayer insulating layer 50 are deposited on the resultant structure.

As integration densities of semiconductor devices are increasing and distances between the semiconductor devices are becoming smaller and smaller, a void 45, as shown in FIG. 5, may be generated when forming, for example, the metal contact etch stop layer 40 and the interlayer insulating layer 50. The metal contact etch stop layer 40 and the interlayer insulating layer 50 are deposited on the entire surface of the semiconductor substrate 10 including the recesses in the field region 12. The interlayer insulating layer 50 is generally a thick layer relative to the metal contact etch stop layer 40.

As shown in FIG. 5, when the interlayer insulating layer 50 does not completely fill the relatively deep recess in the region between the adjacent gate patterns 14 on the field region 12, the void 45 is generated.

Once the void 45 is generated, when a subsequent metal contact filling process is performed, the metal contact fills the void 45 and an electrical short between the adjacent cells results.

### SUMMARY OF THE INVENTION

The invention is therefore directed to a method of fabricating a semiconductor device, and a resultant semiconductor device which substantially overcome one or more of the problems due to the limitations and disadvantages of the related art.

It is a feature of embodiments of the invention to provide a method of fabricating a semiconductor device that prevents a recess from being created on a region between adjacent gate patterns formed on a field region.

It is another feature of embodiments of the invention to provide a method of fabricating a semiconductor device that prevents a void created due to a recess of a field region created in a selective etching process of a silicide blocking layer (SBL) from being generated.

It is yet another feature of embodiments of the invention to provide a method of fabricating a semiconductor device in which a suicide blocking layer is not removed on a region between adjacent gate patterns on a field region of a low resistance device forming region.

It is still another feature of embodiments of the invention to provide a semiconductor device in which an electrical short between adjacent cells is prevented.

At least one of the above and other features and advantages of the invention may be realized by providing a method of fabricating a semiconductor device that involves providing a semiconductor substrate having an active region and a field region, and forming a plurality of gate patterns on each of the active region and the field region, where the plurality of gate patterns each include a sidewall spacer, and the plurality of gate patterns on the field region include at least two adjacent gate patterns. The method may further involve forming a suicide blocking layer pattern that masks a portion of the field region that exists between each pair of the adjacent gate patterns on the field region, and forming a silicide layer on the active region and any of the plurality of gate patterns that are not masked by the silicide blocking layer pattern.

The silicide blocking layer pattern may include an oxide layer and a nitride layer. Forming the silicide blocking layer may involve stacking an oxide layer and a nitride layer on a surface of the semiconductor substrate that includes the plurality of gate patterns, forming a photoresist pattern on the silicide blocking layer, the photoresist pattern overlapping portions of the field region between each of the adjacent gate patterns on the field region, at least one of dry etching and wet etching the nitride layer using the photoresist pattern as a mask to remove any portion of the nitride layer that overlaps an upper surface of the plurality of gate patterns on the field region, removing the photoresist pattern, and cleaning the semiconductor device to form the silicide blocking layer pattern.

Forming the silicide blocking layer pattern may involve forming a silicide blocking layer on a surface of the semiconductor device on which the plurality of gate patterns are formed, forming a photoresist pattern on the silicide blocking layer, the photoresist pattern overlapping portions of the field region between each of the adjacent gate patterns on the field region, trimming the photoresist pattern to form a reduced photoresist pattern, no portion of the reduced photoresist pattern overlapping an upper surface of the plurality of gate patterns on which the silicide layer is to be formed, etching the silicide blocking layer using the reduced photoresist pattern as a mask, removing the reduced photoresist pattern, and cleaning the semiconductor device to form the silicide blocking layer pattern.

The method may involve forming a contact etch stop layer on the semiconductor device, and forming an interlayer insulating layer on an upper surface of the metal contact etch stop layer. A space between each of the two adjacent gate patterns may be about 100 nm or less. The metal contact etch stop layer may be formed to a thickness in a range of about 40 nm to about 100 nm. The field region of the semiconductor substrate may be formed of an oxide layer. Providing the semiconductor substrate may include defining an active region and a field region on the semiconductor substrate including a high resistance device forming region and a low resistance device forming region using a shallow trench isolation (STI) method.

The silicide blocking layer pattern may include an oxide layer and a nitride layer.

At least one of the above and other features and advantages of the invention may be realized by providing a semiconductor device that includes a semiconductor substrate having an active region and a field region defined thereon, a plurality of gate patterns formed on the field region, at least two of the plurality of gate patterns being adjacent to each other, a silicide blocking layer pattern that occupies at least a recess defined by sidewalls of each pair of the adjacent gate patterns, and a silicide layer that is formed on an upper surface of the active region of the semiconductor substrate and on an upper surface of the plurality of gate patterns on the field region.

The silicide blocking layer pattern may include an oxide layer and a nitride layer.

In embodiments, the silicide blocking layer pattern does not to cover an upper surface of the plurality of the gate patterns on the field region.

The semiconductor device may include a metal contact etch stop layer and an interlayer insulating layer that are formed on an upper surface of the silicide layer, an upper surface of the silicide blocking layer pattern and an upper surface of the field region.

A space between each of the two adjacent gate patterns may be about 100 nm or less. The metal contact etch stop layer may have a thickness of about 40 nm to about 100 nm.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1 through 5 illustrate cross-sectional views sequentially illustrating various stages of a known method of fabricating a semiconductor device having a high resistance device forming region and a low resistance device forming region;

FIG. 6 illustrates a cross-sectional view of a semiconductor device structure fabricated by a fabrication method employing one or more aspects of the invention;

FIGS. 7 through 12 illustrate cross-sectional views of a semiconductor device in successive stages of the fabrication process employing one or more aspects of the invention; and

FIGS. 13 through 17 illustrate cross-sectional views of a semiconductor device in successive stages of the fabrication process employing one or more aspects of the invention.

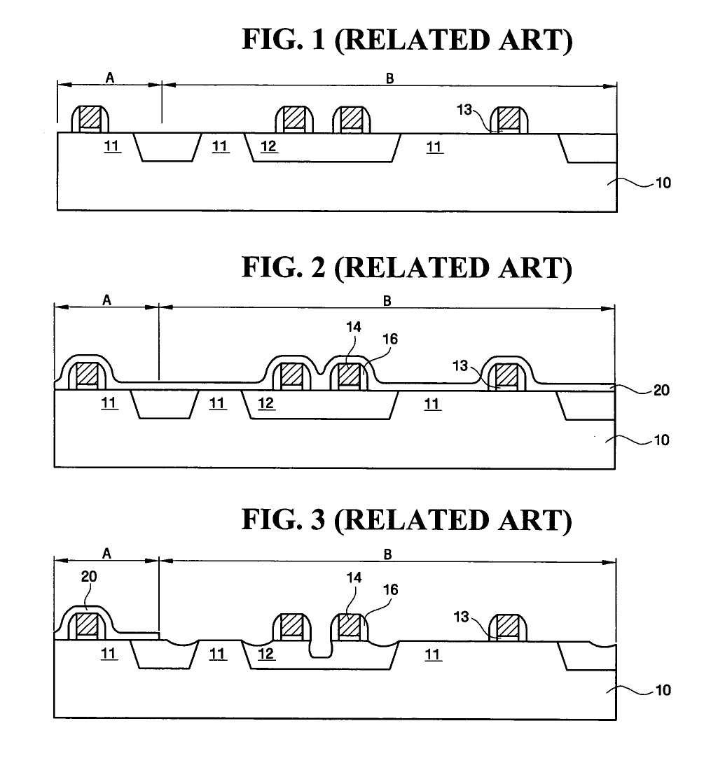

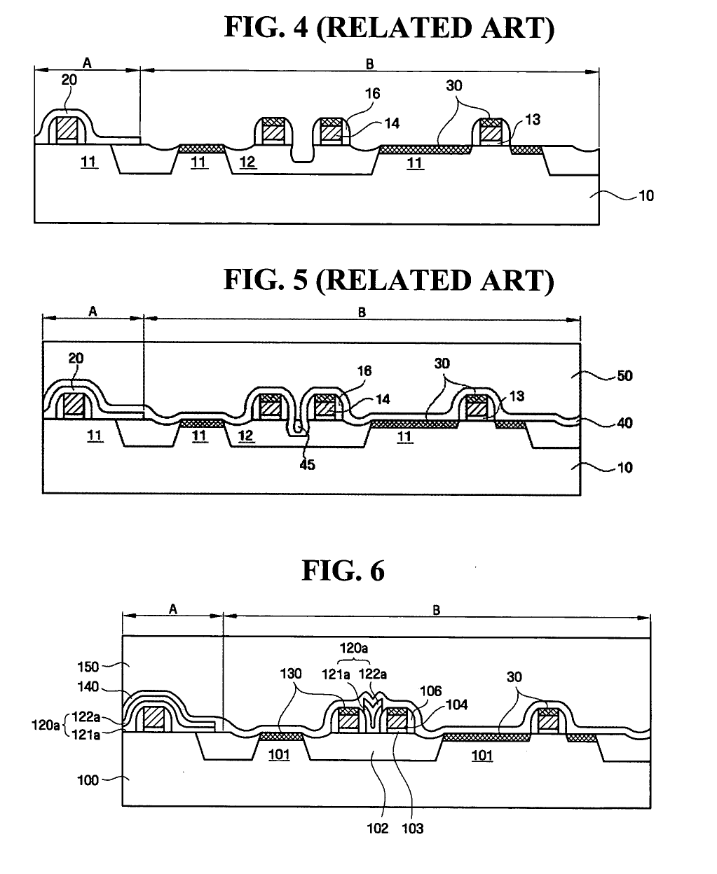

### DETAILED DESCRIPTION OF THE INVENTION

Korean Patent Application No. 10-2005-0007068 filed on Jan. 26, 2005 in the Korean Intellectual Property Office, and entitled: “Method of Fabricating Semiconductor Device Having Silicide Layer and Semiconductor Device Fabricated Thereby,” is incorporated herein by reference in its entirety.

Advantages and features of the invention and methods of accomplishing the same may be understood more readily by reference to the following detailed description of exemplary embodiments and the accompanying drawings. The invention may, however, be embodied in many different forms and should not be construed as being limited to the embodiments set forth herein. Rather, these exemplary embodiments are provided so that this disclosure will be thorough and complete and will fully convey the concept of the invention to those skilled in the art.

In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout the specification.

A semiconductor device fabricated by a fabrication method employing one or more aspects of the invention is described with reference to FIG. 6. As shown in FIG. 6, a semiconductor substrate 100 may have an active region 101 and a field region 102 defined thereon.

The active region 101 may be formed of a silicon layer and the field region 102 may be formed of an oxide layer. The field region 102 may be formed on the active region 101 as a field isolation region is formed by a shallow trench isolation (STI) method.

Gate patterns 104 may be formed adjacent to each other on the field region 102. Gate insulating layers 103 may be formed below the gate patterns 104 and sidewall spacers 106 may be formed on sidewalls of each of the gate patterns 104. In embodiments, gate patterns 104 may be simultaneously or substantially simultaneously formed on the active region 101 and the field region 102.

The plurality of gate patterns 104 may be formed on the active region 101. The gate pattern(s) 104 that are formed on the active region 101 may be used as a gate electrode of a semiconductor device, such as a memory device, and the gate pattern(s) 104 that are formed on the field region 102 may be used to connect gate electrodes of each of cells formed on the active region 101.

Silicide layers 130 may be formed on an surface of the active region 101 and on upper surfaces of the gate patterns 104, respectively. A silicide blocking layer (SBL) pattern 120a may be formed, for example, on a region between the gate patterns 104 that are adjacent to each other. In embodiments, the silicide blocking layer 120a may initially cover an entire surface of the semiconductor device before being patterned, as discussed below.

As shown in FIG. 6, the silicide blocking layer pattern 120a may include an oxide pattern 121a and a nitride pattern 122a. The silicide blocking layer pattern 120a formed on the region between the gate patterns 104 may be formed so as not to cover or overlap with upper surfaces of the gate patterns 104 where, for example, the silicide layers 130 may be formed.

Metal contact etch stop layer 140 may be formed on an upper surface of the silicide layer 130, an upper surface of the silicide blocking layer pattern 120a and an upper surface of the field region 102. An interlayer insulating layer 150 may be formed on an upper surface of the metal contact etch stop layer 140.

The metal contact etch stop layer 140 may be formed to help reduce, and preferably prevent, the silicide layer 130 on the active region 101 from being removed during, for example, an etching process for forming a metal contact on a source/drain region (not shown) of the active region 101. The metal contact etch stop layer 140 may be deposited to a thickness in a range of about 40 nm to about 100 nm. The interlayer insulating layer 150 may be deposited to a thickness that is greater than a thickness of the metal contact etch stop layer 140.

As discussed above, widths of the regions between adjacent gate patterns 104 on a field region 102 are becoming smaller and smaller along with more integration of semiconductor devices. In embodiments of the invention, the width of a region between adjacent gate patterns 104 may be, for example, about 100 nm or less.

As shown in FIG. 6, the silicide blocking layer pattern 120a may be formed on the region(s) between adjacent ones of the gate patterns 104 on the field region 102 of a low resistance device forming region B. The silicide blocking layer pattern 120a may also be formed on the active region 101 of a high resistance device forming region A to help prevent formation of silicide layers 130 the high resistance device forming region A.

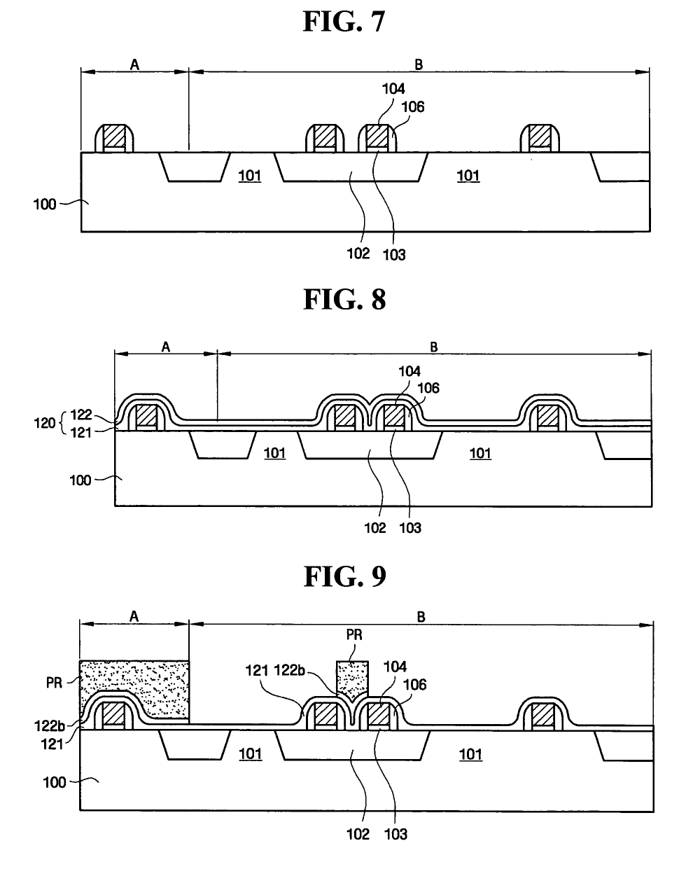

A method of fabricating a semiconductor device according to one embodiment of the invention will be described with reference to FIGS. 7 through 12. FIGS. 7 through 12 illustrate cross-sectional views of a semiconductor device in successive stages of the fabrication process in accordance with an embodiment of the invention.

As shown in FIG. 7, a field isolation region may be formed on a semiconductor substrate 100 by, for example, an STI method, thereby defining the field region 102 and the active region 101. Subsequently, the gate oxide layer 103, the gate pattern 104 and the sidewall spacer 106 may be formed. The gate pattern 104 on the active region 101 may be used as a gate electrode of a semiconductor device such as a memory device. The gate pattern 104 on the field region 102 may be used to connect gate electrodes of each of cells formed on the active region 101.

As shown in FIG. 8, a silicide blocking layer 120 may be deposited on an entire surface of the semiconductor substrate 100.

The silicide blocking layer 120 may be formed to prevent a silicide layer from being formed on a high resistance device forming region A and to prevent a recess from being created in a region between the gate patterns 104 on the field region 102, when fabricating semiconductor devices having the high resistance device forming region A and a low resistance device forming region B on the same semiconductor substrate 100. The suicide blocking layer 120 may include the oxide layer 121 and the nitride layer 122.

Subsequently, as shown in FIG. 9, photoresist may be coated on a resultant structure of FIG. 8. The photoresist may be patterned, thereby forming a photoresist pattern PR that covers, for example, the region between adjacent ones of the gate patterns 104 on the field region 102 and the high resistance device forming region A.

A width of the photoresist pattern PR that covers an upper surface of the region between adjacent ones of the gate patterns 104 may be set in consideration of the resolution of the photoresist and the width of the region between the gate patterns 104. The width of the photoresist pattern PR should be determined including a margin for misalignment. After the photoresist pattern PR is formed, considering the margin for misalignment, to completely cover the region between adjacent ones of the gate patterns 104, a dry etching process may be performed on the nitride layer 122 using the photoresist pattern PR as an etching mask to form an intermediate nitride pattern 122b.

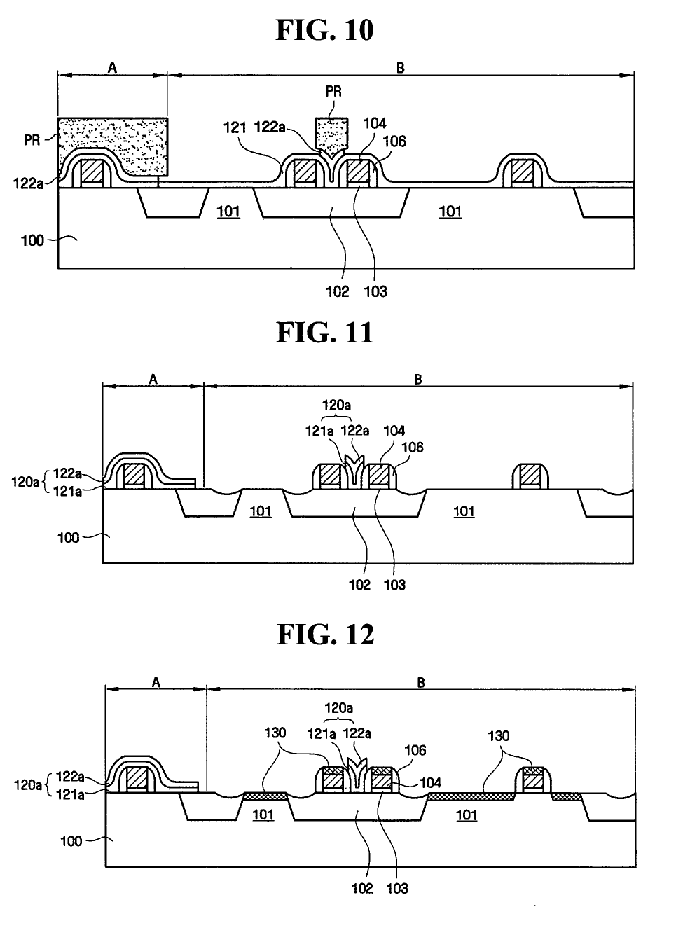

As shown in FIG. 10, a wet etching process may be performed on the dry-etched nitride layer 122 (i.e., the intermediate nitride pattern 122b) using the photoresist pattern PR as an etching mask. Although a portion of the nitride layer 122 may remain (i.e., the intermediate nitride pattern 122a), the remaining portion, if any, should have a width that is small enough to avoid covering the upper surface of adjacent ones of the gate patterns 104.

In embodiments of the invention, the dry etching process and the wet etching process may be performed on the nitride layer 122 to at least remove portions of the nitride layer 122 that may cover the upper surface of the gate patterns 104 (i.e., to form the nitride pattern 122b). In embodiments where there is no misalignment or an insignificant amount of misalignment, the photoresist pattern PR may be formed exactly on the region between adjacent ones of the gate patterns 104 such that the photoresist pattern PR and the intermediate nitride pattern 122b do not to cover the upper surfaces of adjacent ones the gate patterns 104. In such embodiments, it may be possible to not perform the wet etching process.

As shown in FIG. 11, the photoresist pattern PR may be removed. A cleaning process may be performed on the entire surface of the semiconductor substrate 100 as part of the process of forming the suicide layer on the low resistance device forming region B. During the cleaning process, the oxide layer 121 that may be formed on the upper surface of the gate pattern 104, on which the nitride layer 122 is not formed, and an upper surface of the semiconductor substrate 100 may be removed to form the oxide pattern 121a. The silicide blocking layer pattern 120a having the oxide pattern 121a and the nitride pattern 122a may be formed on the high resistance device forming region A and the region between the gate patterns 104 on the field region 102. During the cleaning process, a recess may be created on the surface of the field region 102 formed of an oxide layer.

Next, as shown in FIG. 12, the silicide layer 130 may be formed. The silicide layer 130 may be formed by stacking a metal layer and performing a thermal process to encourage the silicon on the surface of the active region 101 and on the surface of the gate pattern 104 to react with a metal material of the metal layer, to form the silicide layer 130 in a self-aligned manner.

As can be seen in FIG. 6, a metal contact etch stop layer 140 and an interlayer insulating layer 150 may then be sequentially deposited on a resultant structure of FIG. 12. The metal contact etch stop layer 140 may be formed to prevent the silicide layer 130 on the surface of the active region 101 from being removed during, for example, an etching process for forming a metal contact on a source/drain region (not shown) of the active region 101. The metal contact etch stop layer 140 may be deposited to a thickness of about 40 nm to about 100 nm. The interlayer insulating layer 150 may be deposited to a thickness greater than a thickness of the metal contact etch stop layer 140.

As discussed above, with increasing integration of semiconductor devices, a width of the region between adjacent ones of the gate patterns 104 on the field region 102 is becoming much smaller and smaller. In embodiments of the invention, although a width of the region between adjacent ones of the gate patterns 104 may be set to be 100 nm or less, the silicide blocking layer pattern 120a may be formed in the region between the gate patterns 104. The silicide blocking layer pattern 120a may help prevent creation of a recess in the region between adjacent ones of the gate patterns 104. By preventing the creation of a recess, it is also possible to prevent a void from being generated during, for example, a subsequent cleaning process.

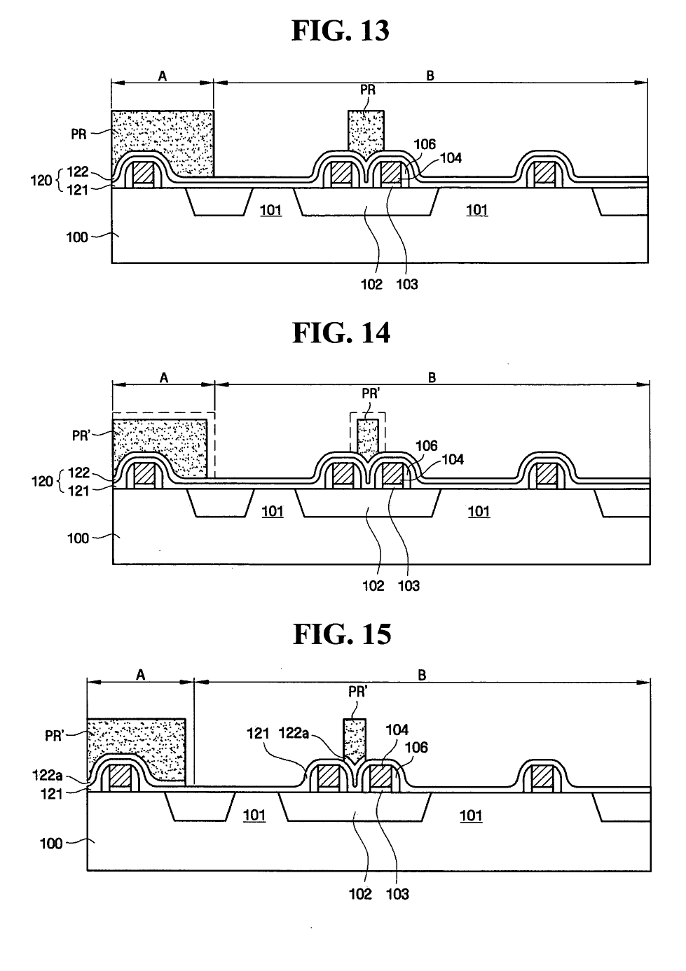

Next, a method of fabricating a semiconductor device according to another embodiment of the invention will be described with reference to FIGS. 13 through 17. FIGS. 13 through 17 illustrate cross-sectional views of a semiconductor device in successive stages of fabrication according to another embodiment of the invention.

In such embodiments, the method of fabricating a semiconductor device includes defining the active region 101 and the field region 102 on a semiconductor substrate 100. The semiconductor substrate may include a high resistance device forming region A and a low resistance device forming region B that is formed by an STI method. The method may involve forming the gate oxide layer 103, the gate pattern 104 and the sidewall spacer 106, and depositing the silicide blocking layer 120 on the entire surface of the resultant structure. The silicide blocking layer 120 may include the oxide layer 121 and the nitride layer 122.

The method of fabricating a semiconductor device according to this embodiment of the invention is substantially the same as the method of fabricating the semiconductor device described in relation to FIGS. 7 through 12. In general, only differences between these embodiments and the embodiments described in relation to FIGS. 7-12 will be discussed below.

After the silicide blocking layer 120 is deposited on the entire surface of the resultant structure, as shown in FIG. 13, a photoresist layer is coated and patterned to form a photoresist pattern PR. The photoresist pattern PR may cover, for example, an upper surface of a region between adjacent ones of the gate patterns 104 on the field region 102 and the high resistance device forming region A.

A width of the photoresist pattern PR may be set in consideration of the resolution of the photoresist and a width of the region between adjacent ones of the gate patterns 104. The width of the photoresist pattern PR should be determined with a margin for misalignment.

The photoresist pattern PR may be formed considering the margin for misalignment and to completely cover at least the region between adjacent ones of the gate patterns 104.

The photoresist pattern PR may be patterned using, for example, a dry etching process, thereby forming a reduced photoresist pattern PR′, as shown in FIG. 14.

As shown in FIG. 15, the nitride layer 122 may then be etched using the reduced photoresist pattern PR′ as an etching mask. Although some of the nitride layer 122 may remain, the remaining nitride pattern 122a should have a width that is small enough to avoid covering or overlapping the upper surface of the gate patterns 104.

In embodiments, after the photoresist pattern PR is formed to completely cover the region between adjacent ones of the gate patterns 104 in consideration of the margin for the misalignment, the photoresist pattern PR may be trimmed. In embodiments where the misalignment is insignificant and/or there is no misalignment, the photoresist pattern PR may be exactly formed on the region between the adjacent ones of the gate patterns 104. In such embodiments, upper surfaces of the gate patterns 104 are not covered with, for example, the photoresist pattern PR, thereby making it possible to skip performing of the additional trimming process.

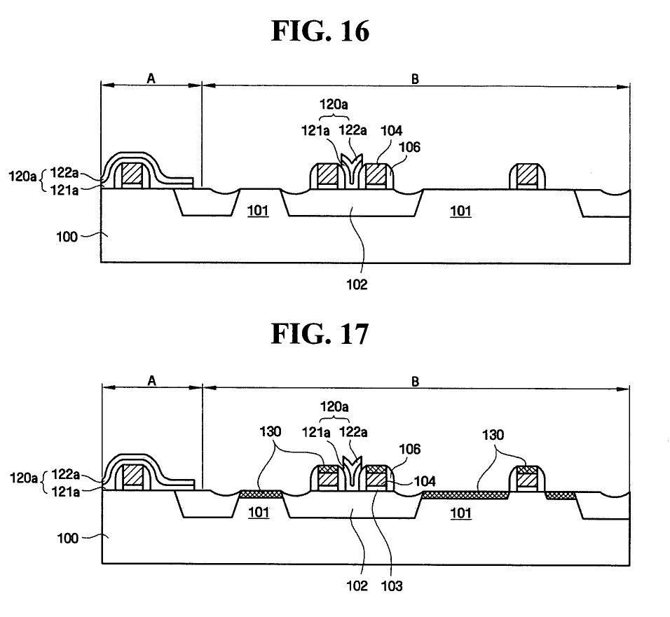

Next, as shown in FIG. 16, the reduced photoresist pattern PR′ may be removed. A cleaning process may be performed, for example, on the entire surface of the semiconductor substrate 100 as part of the process of forming a silicide layer on the low resistance device forming region B. The oxide layer 121 that may be formed on the upper part of the gate pattern 104, on which the nitride layer 122 is not formed, and on an upper part of the semiconductor substrate 100 may be removed. Removal of a portion of the oxide layer 121 (i.e., leaving the oxide pattern 121a) forms the silicide blocking layer pattern 120a. A recess may be created on the surface of the field region 102 formed of an oxide layer during the cleaning process.

Next, as shown in FIG. 17, a metal layer may be deposited and a thermal process may be performed so that silicon on the surface of the active region 101 and on the surface of the gate pattern 104 may react with a metal of the deposited metal layer, thereby forming the silicide layer 130 in a self-aligned manner.

Next, as previously shown in FIG. 6, a metal contact etch stop layer 140 and an interlayer insulating layer 150 may be sequentially deposited on a resultant structure of FIG. 17. The metal contact etch stop layer 140 may be formed to prevent the silicide layer 130 on the surface of the active region 101 from being removed during an etching process for forming a metal contact on a source/drain region (not shown) of the active region 101. The metal contact etch stop layer 140 may be deposited to a thickness of about 40 nm to aobut 100 nm. The interlayer insulating layer 150 may be deposited to a thickness greater than a thickness of the metal contact etch stop layer 140.

A width of the region between adjacent ones the gate patterns 104 on the field region 102 is becoming smaller and smaller with increasing integration of semiconductor devices. Although the width of the region between adjacent ones of the gate patterns 104 may be, for example, about 100 nm or less in embodiments of the invention, the silicide blocking layer pattern 120a may be formed on the region between the adjacent ones of the gate patterns 104 so that a recess is not created in the region between the adjacent gate patterns 104 during a subsequent cleaning process. By preventing the formation of a recess in the region between adjacent ones of the gate patterns 104, it is possible to prevent voids from being generated.

One or more aspects of the invention provide a method of fabricating a semiconductor device including a suicide layer in which a recess may be prevented from being created in a region between adjacent gate patterns on a field region of a semiconductor device.

One or more aspects of the invention provide a method of fabricating a semiconductor device including a silicide layer in which generation of a void, which may be caused by a recess formed, for example, in a field region created during a selective etching process of a silicide blocking layer of the semiconductor device, may be prevented.

One or more aspects of the invention provide a method of fabricating a semiconductor device including a silicide layer in which a suicide blocking layer is not removed in the region between adjacent gate patterns on a field region of a low resistance device forming region of a semiconductor device, thereby preventing occurrence of an electrical short between adjacent cells.

Exemplary embodiments of the invention have been disclosed herein, and although specific terms are employed, they are used and are to be interpreted in a generic and descriptive sense only and not for purpose of limitation. Accordingly, it will be understood by those of ordinary skill in the art that various changes in form and details may be made therein without departing from the spirit and scope of the invention as set forth in the following claims.

What is claimed is:

1. A method of fabricating a semiconductor device, comprising:
providing a semiconductor substrate including an active region and a field region;
forming a plurality of gate patterns on each of the active region and the field region, the plurality of gate patterns each including a sidewall spacer, and the plurality of gate patterns on the field region including at least two adjacent gate patterns;
forming a silicide blocking layer pattern that masks a portion of the field region that exists between each pair of the adjacent gate patterns on the field region; and
forming a silicide layer on the active region and any of the plurality of gate patterns that are not masked by the silicide blocking layer pattern.

2. The method according to claim 1, wherein the suicide blocking layer pattern includes an oxide layer and a nitride layer.

3. The method according to claim 1, wherein forming a silicide blocking layer pattern, comprises:
stacking an oxide layer and a nitride layer on a surface of the semiconductor substrate that includes the plurality of gate patterns;
forming a photoresist pattern on the silicide blocking layer, the photoresist pattern overlapping portions of the field region between each of the adjacent gate patterns on the field region;
at least one of dry etching and wet etching the nitride layer using the photoresist pattern as a mask to remove any portion of the nitride layer that overlaps an upper surface of the plurality of gate patterns on the field region;
removing the photoresist pattern; and
cleaning the semiconductor device to form the silicide blocking layer pattern.

4. The method according to claim 1, wherein forming a silicide blocking layer pattern, comprises:
forming a silicide blocking layer on a surface of the semiconductor device on which the plurality of gate patterns are formed;
forming a photoresist pattern on the silicide blocking layer, the photoresist pattern overlapping portions of the field region between each of the adjacent gate patterns on the field region;
trimming the photoresist pattern to form a reduced photoresist pattern, no portion of the reduced photoresist pattern overlapping an upper surface of the plurality of gate patterns on which the silicide layer is to be formed;
etching the silicide blocking layer using the reduced photoresist pattern as a mask;
removing the reduced photoresist pattern; and
cleaning the semiconductor device to form the silicide blocking layer pattern.

5. The method according to claim 1, further comprising:
forming a metal contact etch stop layer on the semiconductor device; and
forming an interlayer insulating layer on an upper surface of the metal contact etch stop layer.

6. The method according to claim 1, wherein a space between each of the two adjacent gate patterns is about 100 nm or less.

7. The method according to claim 5, wherein the metal contact etch stop layer is formed to a thickness in a range of about 40 nm to about 100 nm.

8. The method according to claim 1, wherein the field region of the semiconductor substrate is formed of an oxide layer.

9. The method according to claim 1, wherein providing the semiconductor substrate comprises:
defining an active region and a field region on the semiconductor substrate including a high resistance device forming region and a low resistance device forming region using a shallow trench isolation (STI) method.

10. The method according to claim 9, wherein the silicide blocking layer pattern includes an oxide layer and a nitride layer.

11. The method according to claim 9, wherein forming a silicide blocking layer pattern comprises:
stacking an oxide layer and a nitride layer on a surface of the semiconductor substrate on which the gate patterns are formed;
forming a photoresist pattern on the silicide blocking layer, the photoresist pattern overlapping portions of the field region between each of the adjacent gate patterns on the field region;
at least one of dry etching and wet etching the nitride layer using the photoresist pattern to remove any portion of the nitride layer that overlaps an upper surface of the plurality of gate patterns on the field region;
removing the photoresist pattern; and
cleaning the semiconductor substrate to form the silicide blocking layer pattern.

12. The method according to claim 9, wherein forming a silicide blocking layer pattern, comprises:
forming a silicide blocking layer on a surface of the semiconductor device on which the plurality of gate patterns are formed;
forming a photoresist pattern on the silicide blocking layer, the photoresist pattern overlapping portions of the field region between each of the adjacent gate patterns on the field region;
trimming the photoresist pattern to form a reduced photoresist pattern, no portion of the reduced photoresist pattern overlapping an upper surface of the plurality of gate patterns on which the silicide layer is to be formed;
etching the silicide blocking layer using the reduced photoresist pattern as a mask;
removing the reduced photoresist pattern; and
cleaning the semiconductor device to form the silicide blocking layer pattern

13. The method according to claim 9, further comprising:
forming a metal contact etch stop layer on the resultant structure; and
forming an interlayer insulating layer on an upper part of the metal contact etch stop layer.

14. The method according to claim 9, wherein a space between each of the adjacent gate patterns is about 100 nm or less.

15. A semiconductor device, comprising:
a semiconductor substrate having an active region and a field region defined thereon;
a plurality of gate patterns formed on the field region, at least two of the plurality of gate patterns being adjacent to each other;
a silicide blocking layer pattern that occupies at least a recess defined by sidewalls of each pair of the adjacent gate patterns; and
a silicide layer that is formed on an upper surface of the active region of the semiconductor substrate and on an upper surface of the plurality of gate patterns on the field region.

16. The semiconductor device according to claim 15, wherein the silicide blocking layer pattern includes an oxide layer and a nitride layer.

17. The semiconductor device according to claim 15, wherein the silicide blocking layer pattern does not to cover an upper surface of the plurality of the gate patterns on the field region.

18. The semiconductor device according to claim 15, further comprising a metal contact etch stop layer and an interlayer insulating layer that are formed on an upper surface of the silicide layer, an upper surface of the silicide blocking layer pattern and an upper surface of the field region.

19. The semiconductor device according to claim 15, wherein a space between each of the two adjacent gate patterns is about 100 nm or less.

20. The semiconductor device according to claim 18, wherein the metal contact etch stop layer has a thickness of about 40 nm to about 100 nm.
